(19) United States
(12) Patent Application Publication
(10) Pub. No.: US 2015/0221845 A1
(43) Pub. Date: Aug. 6, 2015

(54) THERMOELECTRIC CONVERSION DEVICE

(71) Applicants: Chisaki Takubo, Tokyo (JP); Hideaki Takano, Tokyo (JP); Kengo Asai, Tokyo (JP); Takashi Naito, Tokyo (JP); Tadashi Fujieda, Tokyo (JP); Yuichi Sawai, Tokyo (JP); Noriyuki Sakuma, Tokyo (JP)

(72) Inventors: Chisaki Takubo, Tokyo (JP); Hideaki Takano, Tokyo (JP); Kengo Asai, Tokyo (JP); Takashi Naito, Tokyo (JP); Tadashi Fujieda, Tokyo (JP); Yuichi Sawai, Tokyo (JP); Noriyuki Sakuma, Tokyo (JP)

(21) Appl. No.: 14/421,202

(22) PCT Filed: Aug. 31, 2012
(86) PCT No.: PCT/JP2012/072094

§ 371 Date: Feb. 12, 2015

(51) Int. Cl. H01L 35/04; H01L 35/18; H01L 35/20; H01L 35/16

(52) U.S. Cl. CPC H01L 35/04; H01L 35/16; H01L 35/18; H01L 35/20

(57) ABSTRACT

In a thermoelectric conversion device, support substrates (13, 14), electrodes (11, 12) formed on the support substrates and thermoelectric conversion parts (7, 10) formed on the electrodes and containing semiconductor glass are disposed. The semiconductor glass is non-lead glass containing vanadium, and the electrodes contain any of Al, Ti, Ti nitride, W, W nitride, W silicide, Ta, Cr and Si.

This constitution makes it possible to provide a device structure which can be produced by an inexpensive production process, uses a composite material with an excellent thermoelectric conversion characteristic and can solve the characteristic problem of the composite material. As a result, it is possible to provide a thermoelectric conversion device with excellent characteristics and high reliability at a low cost.

### TECHNICAL FIELD

The present invention relates to a thermoelectric conversion device. More specifically, the invention relates to a thermoelectric conversion device which converts heat energy into electrical energy or converts electrical energy into heat energy.

### BACKGROUND ART

Recently, researches on and developments of thermoelectric conversion devices have been actively carried out. A thermoelectric conversion device is a device which recovers exhaust heat released from primary energy into the environment as heat and generates electricity.

As a thermoelectric conversion material constituting a thermoelectric conversion device, for example, a Bi—Te compound is currently often used. This is because this compound shows an excellent thermoelectric conversion property with respect to exhaust heat of a low temperature of 200° C. or lower.

Here, when a thermoelectric conversion device using the thermoelectric conversion material above is produced, a production process in which the thermoelectric conversion material is adhered as a bulk material to an electrode has been used so far. However, the production process has a problem of its high production cost. Specific examples of the production process are a hot-press process by calcining at a high temperature of 500° C. or higher generally under pressure at 10 MPa or more, an electric current sintering process by calcining also using Joule heating caused among the materials due to an electric current, and the like. All of these production processes, however, include a step of applying a high pressure, and steps of producing and cutting bulk materials and individually mounting the bulk materials. These steps are the causes of the high cost.

Regarding this point, there is a production process in which a composite material obtained by mixing a thermoelectric conversion material to be sintered with a sintering aid with a low melting point is calcined. Such a production process is generally called “liquid phase sintering” and employs the following mechanism: when the temperature of the mixed sintering aid exceeds its softening point, only the sintering aid starts to melt ; particles of the thermoelectric conversion material are drawn closer to each other; and the spaces are filled, resulting in the compaction. Therefore, a thermoelectric conversion device can be produced without applying a high pressure. In addition, the time and energy for the individual mounting can be saved when a paste of the composite material is prepared and printed on an electrode. For the reasons above, such a production process in which the composite material is calcined can cut the production cost, as compared to the production processes using a bulk thermoelectric conversion material.

Examples of the production of a thermoelectric conversion device using such a composite material are described in PTL 1, PTL 2 and NPL 1.

PTL 1 especially describes an example in which ceramic particles are used as the thermoelectric conversion material and metal oxide fine particles are used as a combustion aid. According to PTL 1, a thermoelectric conversion device with a high efficiency can be provided because the sintering property of the composite material improves.

PTL 2 describes an example in which an organic material and an inorganic material are combined in a dispersed state, where the inorganic material mainly works as the thermoelectric conversion material and the organic material works as a combustion aid. Here, the organic material is selected from polythiophene or a derivative thereof, a polyphenylene vinylene derivative, a polyparaphenylene derivative, a polyacene derivative, and copolymers of these materials; and the inorganic material is at least one kind selected from Bi—(Te,Se), Si—Ge, Pb—Te, GeTe—AgSbTe, (Co, Ir, Ru) —Sb and (Ca, Sr, Bi) Co₂O₅ materials. According to PTL 2, by hybridizing the organic material and the inorganic material, it is possible to provide a novel composite material which has both of the workability of the organic material and the thermoelectric conversion characteristic of the inorganic material and which can also achieve an n-type thermoelectric conversion characteristic depending on the characteristics of the inorganic material.

NPL 1 describes an example in which Bi—Te is used as an n-type semiconductor thermoelectric conversion material, Sb—Te is used as a p-type semiconductor thermoelectric material and an epoxy resin made from bisphenol F and a curing agent is used as a combustion aid. According to NPL 1, it was possible to produce a thermoelectric conversion device having a thickness of 100 to 200 μm by a printing technique such as a dispenser, and ZT, which is an index of the thermoelectric conversion property, of 0.16 was achieved with the n-type Bi—Te-containing epoxy resin and ZT of 0.41 was achieved with the p-type Sb—Te-containing epoxy resin.

In addition, as another conventional example regarding a thermoelectric conversion device, the relationships between thermoelectric conversion materials and electrode materials and binding materials are examined in PTL 3. PTL 3 describes an example in which a barrier metal is interposed between a thermoelectric conversion material and an electrode in order to prevent the electrode material and the binding material from degenerating the thermoelectric conversion material.

### CITATION LIST

### Patent Literature

PTL 1: JP-A-2010-225719

PTL 2: JP-A-2003-46145

PTL 3: JP-A-2003-273414

### Non Patent Literature

NPL 1: Deepa Madan, Alic Chen, Paul K. Wright, and James W. Evans: Dispenser printed composite thermoelectric thick films for thermoelectric generator applications. J. Appl. Phys. 109, 034904 (2011)

### SUMMARY OF INVENTION

### Technical Problem

When the composite materials described in PTL 1, PTL 2 and NPL 1 are used, simple production processes such as screen printing and coating can be used for producing a thermoelectric conversion device by using pastes of the composite materials and thus a thermoelectric conversion device can be produced at a low cost.

However, none of the composite materials described in the literatures above is the best combination of materials for a thermoelectric conversion device.

Specifically, metal oxide fine particles are used as the combustion aid in PTL 1. Because the metal oxide fine particles do not have the thermoelectric conversion function, the thermoelectric conversion property of the composite material described in PTL 1 as a whole mixture is inhibited. In addition, with respect to the composite material described in PTL 2, because the thermoelectric conversion characteristic of the organic material is poor, the thermoelectric conversion property of the whole mixture is similarly inhibited. In NPL 1, an epoxy resin is used as the combustion aid. However, since the epoxy resin does not have the thermoelectric conversion function, either, the thermoelectric conversion property of the composite material of NPL 1 is also inhibited as in PTL 2. Moreover, because the softening point of the epoxy resin is low, the applications of the composite material of NPL 1 are limited to those for around room temperature.

Accordingly, a composite material having a better thermoelectric conversion property is desired to be provided. In this respect, the inventors of the present application have examined especially non-lead glass containing vanadium as the thermoelectric conversion material of the composite material. As a result, the inventors of the application have found that when a thermoelectric conversion device is produced using a paste of a composite material containing the thermoelectric conversion material, a new problem arises between the composite material and an electrode in the step of calcining at a high temperature after printing or coating the paste on the electrode. This problem is a new problem which does not arise in the production processes using a bulk material obtained by sintering a semiconductor thermoelectric conversion material powder, such as the process of PTL 3, and the problem is described in none of the citations. The details of the problem are described below in Examples.

In view of the above points, an object of the invention is to provide a device structure which can be produced by an inexpensive production process, uses a composite material with an excellent thermoelectric conversion characteristic and can solve the characteristic problem of the composite material, and thus provide a thermoelectric conversion device with excellent characteristics and high reliability at a low cost.

### Solution to Problem

A representative example of the means to accomplish the object according to the invention of the application is a thermoelectric conversion device which contains a support substrate, an electrode formed on the support substrate, and a thermoelectric conversion part formed on the electrode and containing semiconductor glass, and which is characterized in that the semiconductor glass is non-lead glass containing vanadium, and the electrode contains any of Al, Ti, Ti nitride, W, W nitride, W silicide, Ta, Cr and Si.

### Advantageous Effects of Invention

According to the invention, a thermoelectric conversion device with excellent characteristics and high reliability can be provided at a low cost.

### BRIEF DESCRIPTION OF DRAWINGS

FIG. 1 is a cross-sectional schematic diagram showing a thermoelectric conversion device according to Example 1.

FIG. 2 is a cross-sectional schematic diagram showing a thermoelectric conversion composite material according to Example 1 before calcination.

FIG. 3 is a cross-sectional schematic diagram showing the thermoelectric conversion composite material according to Example 1 after sintering.

FIG. 4A is a SEM image showing a thermoelectric conversion composite material made from semiconductor glass and a semiconductor thermoelectric conversion material before calcination.

FIG. 4B is a SEM image showing a thermoelectric conversion composite material made from semiconductor glass and a semiconductor thermoelectric conversion material after calcination.

FIG. 5 is an optical microscope observation image of an Au electrode degenerated after calcining a formed thermoelectric conversion composite material at 500° C.

FIG. 6 is a SEM observation image of a degenerated area of a thermoelectric conversion composite material and an electrode.

FIG. 7 shows a SEM image of the enlargement of the degenerated area of the electrode shown in FIG. 6, and results of component analysis of the same area by EDX (energy dispersive X-ray analyzer).

FIG. 8 are results of evaluation of presence or absence of aggregation of electrode materials due to thermoelectric conversion composite materials.

FIG. 9 is a cross-sectional schematic diagram showing another example of the thermoelectric conversion device according to Example 1.

FIG. 10A is a cross-sectional schematic diagram showing the production process of the thermoelectric conversion device according to Example 1.

FIG. 10B is a cross-sectional schematic diagram showing the production process of the thermoelectric conversion device according to Example 1.

FIG. 10C is a cross-sectional schematic diagram showing the production process of the thermoelectric conversion device according to Example 1.

FIG. 10D is a cross-sectional schematic diagram showing the production process of the thermoelectric conversion device according to Example 1.

FIG. 10E is a cross-sectional schematic diagram showing the production process of the thermoelectric conversion device according to Example 1.

FIG. 10F is a cross-sectional schematic diagram showing the production process of the thermoelectric conversion device according to Example 1.

FIG. 10G is a cross-sectional schematic diagram showing the production process of the thermoelectric conversion device according to Example 1.

FIG. 11 is a cross-sectional schematic diagram showing a thermoelectric conversion device according to Example 2.

FIG. 12 is a cross-sectional schematic diagram showing a thermoelectric conversion device according to Example 3.

FIG. 13A is a cross-sectional schematic diagram explaining the flow of an electric current of a thermoelectric device.

FIG. 13B is a cross-sectional schematic diagram explaining the flow of an electric current of a thermoelectric conversion device.

FIG. 14A is a cross-sectional schematic diagram showing the production process of a thermoelectric conversion device according to Example 4.

FIG. 14B is a cross-sectional schematic diagram showing the production process of the thermoelectric conversion device according to Example 4.

FIG. 14C is a cross-sectional schematic diagram showing the production process of the thermoelectric conversion device according to Example 4.

FIG. 15A is a cross-sectional schematic diagram showing another example of the production process of a thermoelectric conversion device according to Example 4.

FIG. 15B is a cross-sectional schematic diagram showing another example of the production process of the thermoelectric conversion device according to Example 4.

FIG. 15C is a cross-sectional schematic diagram showing another example of the production process of the thermoelectric conversion device according to Example 4.

FIG. 15D is a cross-sectional schematic diagram showing another example of the production process of the thermoelectric conversion device according to Example 4.

FIG. 15E is a cross-sectional schematic diagram showing another example of the production process of the thermoelectric conversion device according to Example 4.

FIG. 15F is a cross-sectional schematic diagram showing another example of the production process of the thermoelectric conversion device according to Example 4.

FIG. 15G is a cross-sectional schematic diagram showing another example of the production process of the thermoelectric conversion device according to Example 4.

### DESCRIPTION OF EMBODIMENTS

### EXAMPLE 1

### <Device Structure>

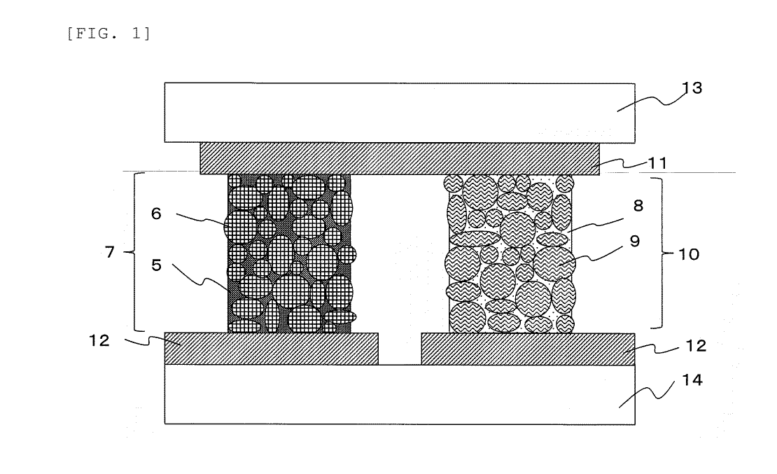

FIG. 1 is a cross-sectional schematic diagram showing an example of the thermoelectric conversion device according to Example 1. The thermoelectric conversion device according to this Example has a structure containing electrodes formed on support substrates and thermoelectric conversion composite materials formed and sintered on the electrodes, in which the thermoelectric conversion composite materials are electrically directly connected in such a way that the polarities of neighboring thermoelectric conversion composite materials are alternate. Specifically, it is a π-type thermoelectric conversion device obtained by connecting a p-type thermoelectric conversion part 7 made from a thermoelectric conversion composite material in which a p-type semiconductor thermoelectric conversion material 6 is combined with a semiconductor glass 5 as the base material, and an n-type thermoelectric conversion part 10 made from a thermoelectric conversion composite material in which an n-type semiconductor thermoelectric conversion material 9 is combined with a semiconductor glass 8 as the base material, to an upper electrode 11 and a lower electrode 12. The upper electrode 11 and the lower electrode 12 are formed on an upper support substrate 13 and a lower support substrate 14, respectively.

### <Semiconductor Glass>

The details of the semiconductor glass contained in the thermoelectric conversion composite material are explained below. The semiconductor glass according to this Example is a non-lead glass containing vanadium. This semiconductor glass is a material having the characteristic of softening at a temperature lower than a melting point of the semiconductor thermoelectric conversion material, and its softening point can be set at 480° C. or lower, for example. Accordingly, such semiconductor glass can be used as a sintering aid for sintering the thermoelectric conversion composite material.

The property of a thermoelectric conversion material is represented by equation (1) as a dimensionless figure of merit ZT. S is Seebeck coefficient, σ is electrical conductivity, κ is thermal conductivity, and T is operation temperature. The larger ZT is, the higher the thermoelectric conversion efficiency is.

ZT=(Ŝ2×σ×T)/κ Equation (1)

In general, when a composite material is used as a thermoelectric conversion material, Seebeck coefficient and the electrical conductivity tend to decrease by the composite formation. The thermoelectric conversion composite materials cited in PTL 1, PTL 2 and NPL 1 all show this tendency. On the other hand, when non-lead glass containing vanadium is used as a combustion aid, the decreases of Seebeck coefficient and the electrical conductivity caused by the composite formation are both prevented and thus the material is a favorable thermoelectric conversion composite material with an excellent thermoelectric conversion characteristic.

Here, the change of the form of the sintering aid in a sintering step is explained using FIGS. 2 to 4.

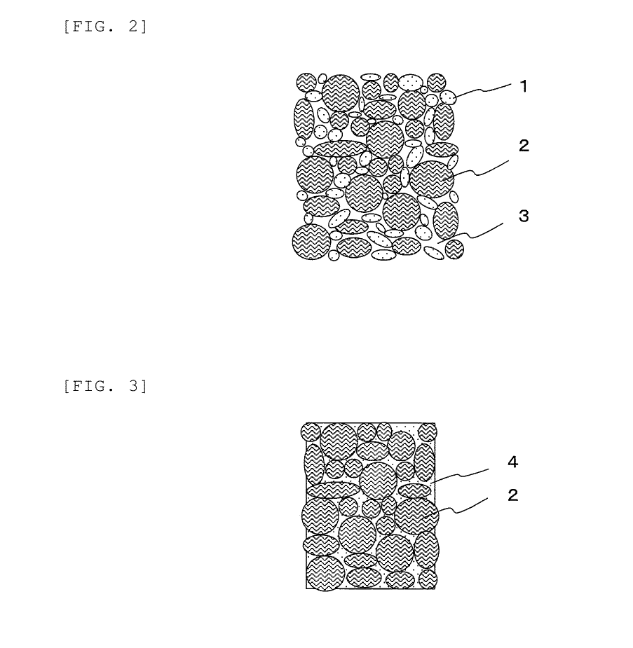

FIG. 2 shows the state before sintering, where a thermoelectric conversion material paste made from a thermoelectric conversion composite material obtained by mixing a semiconductor thermoelectric conversion material and semiconductor glass powder as the sintering aid was formed and a solvent and a binder were vaporized by drying and pre-calcination. As shown in FIG. 2, a semiconductor glass powder 1 and a semiconductor thermoelectric conversion material 2 are in contact with each other in a powder state and much space 3 exists among them. When calcined at the softening point of the semiconductor glass or higher after this, only the semiconductor glass melts as in FIG. 3 and the space among a semiconductor glass 4 and the semiconductor thermoelectric conversion material 2 becomes smaller, resulting in the compaction of the thermoelectric conversion composite material.

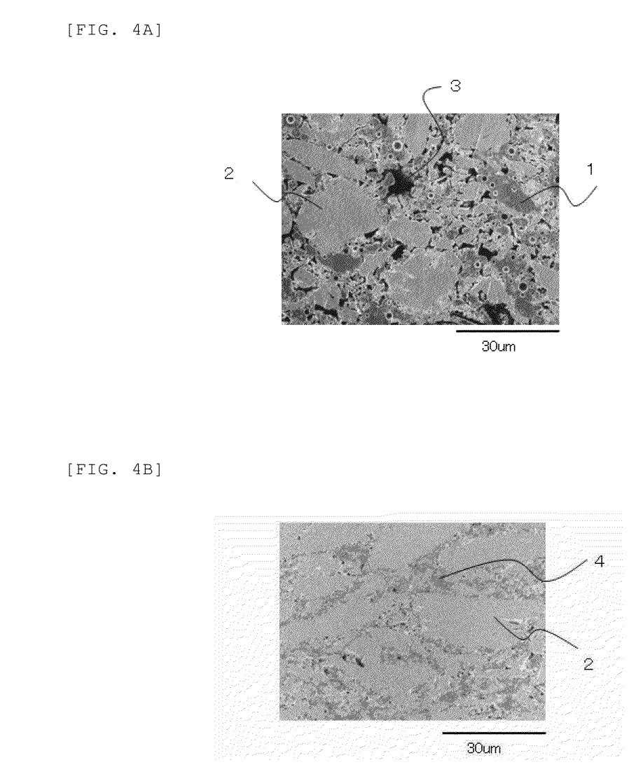

FIG. 4 includes cross-sectional SEM images of a thermoelectric conversion composite material before and after the semiconductor glass has melted. Before calcining the semiconductor glass powder as shown in FIG. 4A, much space 3 exists among the semiconductor glass powder 1 and the semiconductor thermoelectric conversion material 2. On the other hand, after calcining the semiconductor glass as shown in FIG. 4B, it can be seen that the space among the melted semiconductor glass 4 and the semiconductor thermoelectric conversion material 2 has become smaller and as a result the thermoelectric conversion composite material has been compacted.

Here, the semiconductor glass has a property that it can be a p-type semiconductor or an n-type semiconductor by the adjustment of the balance of valencies of vanadium ions in the glass. When the ratio of the concentration of pentavalent vanadium ions (V⁵⁺) to the concentration of tetravalent vanadium ions (V⁴⁺) is smaller than 1, the semiconductor glass is a p-type; while when the ratio is larger than 1, the semiconductor glass is an n-type. Accordingly, by adjusting the balance of valencies of vanadium ions (namely, [V⁵⁺]/[V⁴⁺]) with additive elements, the polarity of the semiconductor glass can be controlled. For example, when the polarity of the semiconductor glass should be a p-type ([V⁵⁺]/[V⁴⁺]<1), an element having an effect to reduce divanadium pentoxide (V₂O₅) can be added. Specifically, when components are represented in terms of their oxides, at least one kind or more of diarsenic trioxide (As₂O₃), iron (III) oxide (Fe₂O₃), antimony trioxide (Sb₂O₃), bismuth (III) oxide (Bi₂O₃), tungsten trioxide (WO₃), molybdenum trioxide (MoO₃) and manganese oxide (MnO) can be added. On the other hand, when the polarity of the semiconductor glass should be an n-type ([V⁵⁺]/[V⁴⁺]>1), an element which inhibits the reduction of divanadium pentoxide (V₂O₅) can be added. Specifically, when components are represented in terms of their oxides, at least one kind or more of silver (I) oxide (Ag₂O), copper (II) oxide (CuO), an oxide of an alkali metal and an oxide of an alkaline earth metal can be added.

As described above, the semiconductor glass in the thermoelectric conversion composite material of this Example has a property that it can be a p-type semiconductor or an n-type semiconductor by the adjustment of the balance of valencies of vanadium ions in the glass. Accordingly, it is possible to make the polarity of the semiconductor glass correspond to the polarity of the semiconductor thermoelectric material, both for the n-type and p-type thermoelectric conversion composite materials, and thus there is an effect that the thermoelectric conversion characteristic of the thermoelectric conversion composite material as a whole is not impaired.

In this regard, more specifically, the semiconductor glass preferably contains tellurium dioxide (TeO₂) or diphosphorus pentoxide (P₂O₅), and when all the contained vanadium oxides are converted to divanadium pentoxide (V₂O₅), the total percentage of divanadium pentoxide, tellurium dioxide and diphosphorus pentoxide is preferably 60% by mass or more.

### <Semiconductor Thermoelectric Conversion Material>

Next, the optimum material can be selected as the semiconductor thermoelectric conversion material contained in the thermoelectric conversion composite material, depending on the temperature for the use. For example, in case of the use at 200° C. or lower, a Bi—(Te,Sb) material can be preferably used. Also, in addition to the above material, for example, a Bi—(Te, Se, Sn, Sb) material, a Pb—Te material, a Zn—Sb material, an Mg—Si material, an Si—Ge material, a GeTe—AgSbTe material, a (Co, Ir, Ru) —Sb material, a (Ca, Sr, Bi) Co₂O₅ material, an Fe—Si material, an Fe—V—Al material or the like can be preferably used. Furthermore, it is also possible to combine semiconductor thermoelectric conversion materials with different temperatures for the uses in order to cover a wide range of temperature.

### <Thermoelectric Conversion Composite Material>

By preparing a thermoelectric conversion material paste from the thermoelectric conversion composite material containing the semiconductor glass and the semiconductor thermoelectric material described above, a thermoelectric conversion device can be produced. The thermoelectric conversion material paste can be produced by adding a solvent and a resin binder to the thermoelectric conversion composite material. For example, butyl carbitol acetate or α-terpineol can be used as the solvent, and for example, ethylcellulose or nitrocellulose can be used as the resin binder.

### <Problem Accompanying Reaction of Semiconductor Glass and Electrode Material>

In order to produce the thermoelectric conversion device according to this Example, it is necessary to sinter the thermoelectric conversion composite material in a calcining step at a temperature of the softening point or higher to soften and melt the semiconductor glass used as the combustion aid.

Here, the inventors of the application examined what reaction occurred at the thermoelectric conversion material and the electrode when the temperature was raised. As a result, it was found by the experiment that the electrode material sometimes degenerates because vanadium and tellurium, which are the components of the semiconductor glass, vaporize and adhere to the surrounding electrode again.

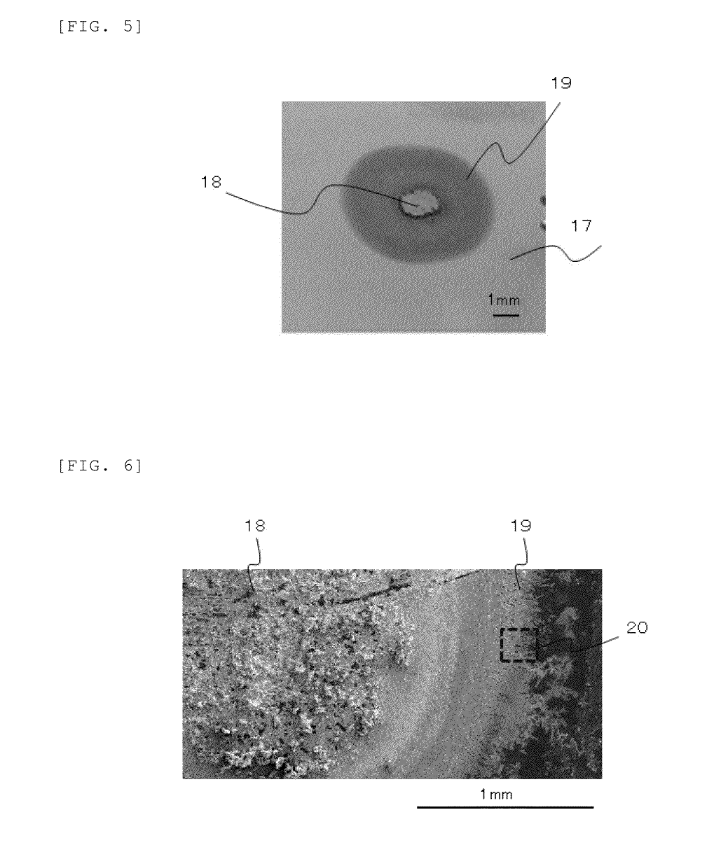

FIG. 5 shows an optical microscope image of an electrode degenerated when a thermoelectric conversion composite material 18 containing the semiconductor glass as the base material was coated on an Au electrode 17, dried at 150° C., pre-calcined at 380° C. and calcined at 500° C. The blurred area around the thermoelectric conversion composite material 18 is a degenerated area 19 of the Au electrode. In addition, an image of SEM (scanning electron microscope) observation of the degenerated area is shown in FIG. 6. There is the degenerated area 19 in the electrode outside of the thermoelectric conversion composite material 18. In addition, a SEM image in which a part 20 of the degenerated area of the electrode was enlarged and observed, and the results of the component analysis of the same area by EDX (energy dispersive X-ray analyzer) are shown in FIG. 7. In the EDX results, white areas are where the analyte substance was detected. From the SEM image of (a), it can be seen that there is a substance in a particle form in the degenerated area of the electrode. As a result of the component analysis of the particles, Au 21 was detected at the same locations as the particles also in the EDX analysis result (b) of Au as the original electrode material, and Au was not detected around the particles. From this, it was found that the particles observed in the SEM image are aggregates of thin films of Au. In addition, when the components detected were examined, V (vanadium) and Te (tellurium), which are the components of the semiconductor glass, were detected at the same locations as the particles, as shown in the results in (c) and (d). From these results, it is thought that vanadium and tellurium, which vaporized from the semiconductor glass and adhered to the surrounding electrode, reacted with the electrode material and the electrode material aggregated. When the electrode material aggregates, the electrode is partially cut and the resistance of the electrode may increase. In addition, when the electrode is cut at many places, it is thought that the electrode may break. Such aggregation and break of the electrode are the causes for the deterioration of the reliability of the thermoelectric conversion device.

Thus, it has been found for the first time in this experiment that there is a problem that the Au electrode aggregates due to the vaporized components of the semiconductor glass when the thermoelectric conversion composite material in which the semiconductor glass according to this Example as the base material is combined with the semiconductor thermoelectric conversion material is formed on the Au electrode and calcined. Based on this experimental result, the inventors of the application investigated electrode materials which do not aggregate due to the thermoelectric conversion composite material, for purpose of providing a thermoelectric conversion device having an electrode whose reliability is not deteriorated by the thermoelectric conversion composite material.

As the electrode materials, Ti, TiN, W, WN, WSi, Ta, Cr, Poly Si, Al, Au, Pt, Mo, MoN, Ni, Co, Fe, Ag and Cu were selected from materials that are relatively often used in general production steps of semiconductors and materials used for conventional thermoelectric conversion devices using bulk materials, and these materials were examined. In addition, regarding the thermoelectric conversion composite material, Bi_{0.3}Sb_{1.7}Te₃ was used as the p-type semiconductor thermoelectric conversion material, and a material containing vanadium oxides and diphosphorus pentoxide (P₂O₅) was used as the p-type semiconductor glass. Furthermore, Bi₂Te₃ was used as the n-type semiconductor thermoelectric conversion material and a material containing vanadium oxides and tellurium dioxide (TeO₂) was used as the n-type semiconductor glass. The same experiment was thus conducted.

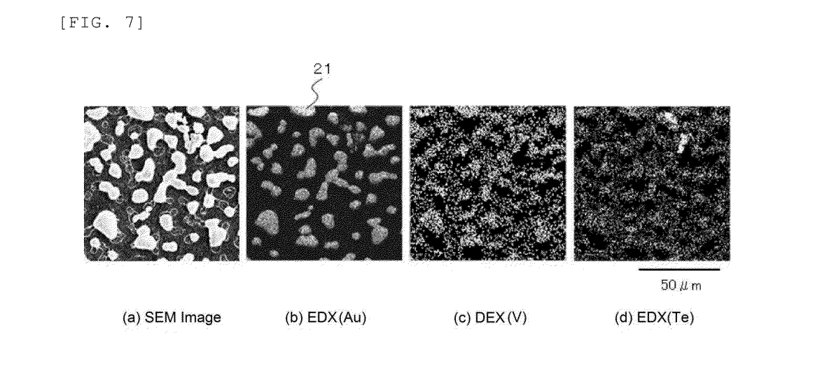

A substrate in which a film of an electrode material was formed on an oxide film-containing silicon substrate was prepared and a paste obtained by mixing a solvent and a binder to the thermoelectric conversion composite material was coated on the electrode. By drying at 150° C. for 10 minutes, which is the same condition as in the process flow of the thermoelectric conversion device described below, pre-calcining at 380° C. for 30 minutes and then calcining at 500° C., which is higher than the softening point of the glass, a sample was produced. Samples were evaluated by SEM observation as to whether the electrode materials around the coated paste aggregated or not. The evaluation results are shown in FIG. 8, where those in which the aggregation of the electrode material was not generated are indicated with ∘ and those in which aggregation was generated are indicated with ×. As a result of the evaluation, no aggregation was generated with Ti, Ti nitride, W, W nitride, W silicide, Ta, Cr, Si and Al: while aggregation was generated with Au, Pt, Mo, MoN, Ni, Co, Fe, Ag and Cu. From these results, it was found that it is possible to provide a thermoelectric conversion device in which the increase in the resistance or the break due to the partial cuts in the electrode does not occur, when the material of the outermost surface of the electrode is any of Ti, Ti nitride, W, W nitride, W silicide, Ta, Cr, Si and Al.

In this regard, in the explanations up to here, an example in which the thermoelectric conversion part is a composite material of the n-type (or p-type) semiconductor thermoelectric conversion material and the semiconductor glass has been explained; however, the constitution of the thermoelectric conversion device according to this Example is not limited to this example and it is also possible that the thermoelectric conversion part is composed of the semiconductor glass only as in FIG. 9. The reason for this is as follows.

From equation (1) described above, it can be seen that ZT can be increased when the electrical conductivity σ can be increased. In connection with this, in the thermoelectric conversion device according to this Example, when the volume percent of the semiconductor glass as the base material becomes 50% by volume or more, the area at which the particles of the semiconductor thermoelectric conversion material contact each other decreases and thus the thermoelectric conversion property corresponding to the semiconductor thermoelectric conversion material deteriorates. However, the electrical conductivity a of the glass increases significantly by crystallizing the semiconductor glass and thus the thermoelectric property of the thermoelectric conversion composite material can be achieved. By using the p-type semiconductor glass 6 and the n-type semiconductor glass 8 which have the above property as the thermoelectric conversion parts as shown in FIG. 9, a thermoelectric conversion device with a necessary thermoelectric conversion efficiency can be produced.

In particular, because a Bi—Te semiconductor thermoelectric conversion material contains large amounts of Te, which is a rare metal, and Bi, which is obtained as a by-product of lead for which the environmental regulation has been tightened, when a thermoelectric conversion device is produced from a thermoelectric conversion material which does not contain the semiconductor thermoelectric conversion material but contains the semiconductor glass only as in FIG. 9, a thermoelectric conversion device which imposes smaller environmental burden can be achieved at a lower cost.

Considering the above points, the thermoelectric conversion device according to this Example contains a support substrate (13 or 14), an electrode (11 or 12) formed on the support substrate and a thermoelectric conversion part (7 or 10) formed on the electrode and containing semiconductor glass, and is characterized in that the semiconductor glass is non-lead glass containing vanadium and the electrode contains any of Al, Ti, Ti nitride, W, W nitride, W silicide, Ta, Cr and Si.

From the above characteristics, the thermoelectric conversion device according to this Example can be produced by a less expensive production process than conventional processes because non-lead glass containing vanadium is used as the thermoelectric conversion material, and a thermoelectric conversion device with excellent characteristics can be achieved at a low cost because a material with an excellent thermoelectric conversion characteristic is used. Furthermore, because the electrode is made from the above materials, the electrode materials do not aggregate even when the materials of the semiconductor glass vaporize. Thus, the resistance of the electrode can be prevented from increasing, and the break in the worst case can be also prevented. Accordingly, a thermoelectric conversion device with high reliability can be achieved.

In addition, the thermoelectric conversion part also contains a semiconductor thermoelectric conversion material, and a constitution in which the semiconductor thermoelectric conversion material contains at least one kind of a Bi—(Te, Se, Sn, Sb) material, a Pb—Te material, a Zn—Sb material, an Mg—Si material, an Si—Ge material, a GeTe—AgSbTe material, a (Co, Ir, Ru) —Sb material, a (Ca, Sr, Bi) Co₂O₅ material, an Fe—Si material and an Fe—V—Al material is possible. With such a constitution, a thermoelectric conversion device with better thermoelectric conversion property can be achieved.

On the other hand, as explained in FIG. 9, a constitution in which the thermoelectric conversion part does not contain the semiconductor thermoelectric conversion material is also included in the thermoelectric conversion device according to this Example. With such a constitution, a thermoelectric conversion device which imposes smaller environmental burden can be achieved at a lower cost.

In this regard, as compared to Example 3 described below, the thermoelectric conversion device according to this Example has a characteristic that the electrode is in direct contact with the thermoelectric conversion part. Due to this characteristic, it is not necessary to add a special layer, such as the binding layer of Example 3 described below, and thus there is an effect that the production cost can be cut.

### <Production Process>

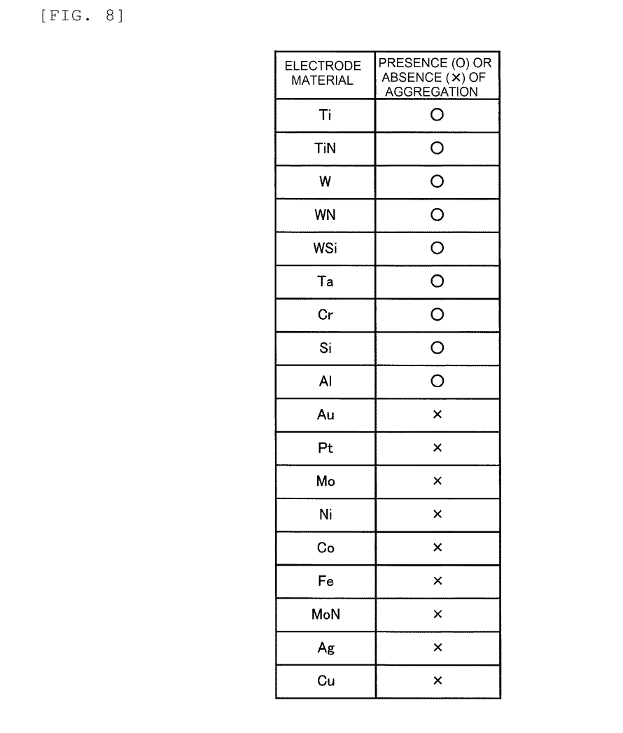

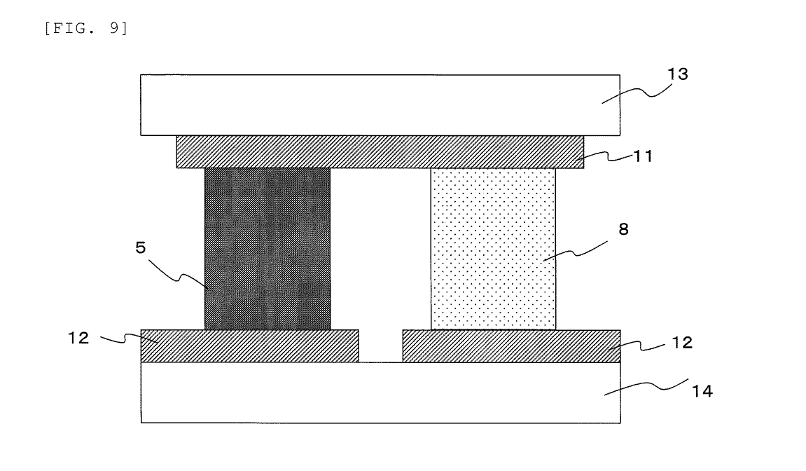

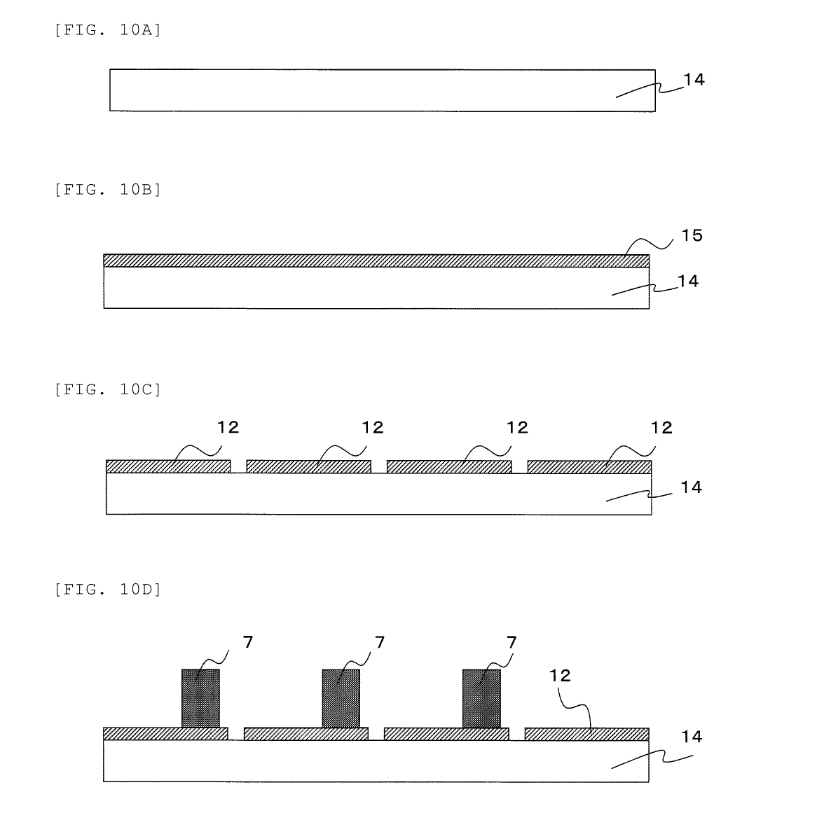

An example of the production process of the thermoelectric conversion device of the invention is explained using FIG. 10. In general, regarding a thermoelectric conversion device, many π-type devices are connected in series in order to increase the power generation. In FIG. 10, however, cross-sections of only three pairs of π-type thermoelectric conversion devices are shown and the rest is not shown.

In FIG. 10A, the lower support substrate 14 is shown. The lower support substrate 14 supports the electrodes and the thermoelectric composite materials and a case in which an insulating substrate is used is shown here. On the other hand, when an electrically conductive support substrate is used as the lower support substrate 14, an insulating layer may be formed between the surface of the support substrate and the electrodes in order to insulate from the electrodes formed on the support substrate. In addition, the lower support substrate 14 has to be formed from a material with a high thermal conductivity in order to efficiently transmit the heat supplied to the thermoelectric device from outside to the semiconductor thermoelectric conversion composite materials. Furthermore, the resistance to heat up to about 500 to 600° C., which is the calcination temperature of the thermoelectric composite materials, is necessary. As long as these conditions are met, the lower support substrate 14 may be a hard substrate or a flexible substrate. An insulator substrate such as alumina and a conductor (including semiconductor) substrate such as a metal plate are desirable as the hard substrate, and a heat-resistant flexible sheet and a metal foil are desirable as the flexible substrate.

A cross-sectional diagram of the lower support substrate 14 on which an electrode film 15 has been formed by vapor deposition, sputtering or the like is shown in FIG. 10B. For the film formation, because the amperage of the electric current flowing in the thermoelectric conversion device varies according to the kind of the semiconductor thermoelectric conversion material used, the thickness of the electrode film 15 should be a thickness suitable for the amperage. For example, when a Bi—Te material, which has a low electrical conductivity, is used as the semiconductor thermoelectric conversion material, the amperage of the electric current that flows is not high and thus a thickness of the electrode of several hundred nm is sufficient. On the other hand, when an Fe—V—Al material, which has a high electrical conductivity, is used as the semiconductor thermoelectric conversion material, the amperage of the electric current that flows is also high and thus a thickness of the electrode of several hundred nm to 1 μm or more is rather desirable.

Next, a cross-sectional diagram after forming electrodes 12 is shown in FIG. 10C. As the process for forming electrodes 12, in addition to a process by patterning by photolithography or etching after forming the film, there is a process by printing an electrode pattern by screen printing or inkjet printing or using a dispenser or the like and calcining. In addition, when a thick metal plate, a metal foil or the like is used as the lower support substrate 14, the substrate can be used as the electrode as it is. When a small, light device such as those for energy harvesting is necessary, it is more appropriate to draw a pattern of the electrodes on the support substrate. This is because the electrodes 12 can be formed by fine patterning even when any of the patterning processes is used, because the electrode film 15 can be formed with a thickness of several dozen nm to several μm, which is smaller than those of a thick metal plate and a metal foil.

Next, a cross-sectional diagram after coating and forming the p-type (or n-type) thermoelectric conversion parts 7 is shown in FIG. 10D. Here, powder of Bi_{0.3}Sb_{1.7}Te₃ (70% by volume) resulting in a p-type semiconductor thermoelectric conversion material, and semiconductor glass powder (30% by volume) containing vanadium oxides, diphosphorus pentoxide (P₂O₅) and antimony trioxide (Sb₂O₃) were used for the p-type thermoelectric conversion composite material. In addition, a mixture of butyl carbitol acetate (BCA) as the solvent and ethylcellulose (EC) as the binder in an amount of 15% by mass was added thereto and the obtained thermoelectric conversion material paste was used.

Here, the paste was coated using a stencil printing process and formed into a size of an area of 1 mm×1 mm and a thickness (height) of 100 μm. Screen printing and a patterning process using a thick film resist which is used to produce a rib of a PDP (plasma display panel) (explained in Example 6) may be also used.

Similarly, as shown, a cross-sectional diagram in which a substrate obtained by forming thermoelectric conversion parts 10 of the other n-type (or p-type) on the upper support substrate 13 to which a pattern of the upper electrodes 11 has been drawn has been formed is shown in FIG. 10E. Here, because the substrate is to be adhered to the substrate in which the p-type (or n-type) thermoelectric conversion parts is formed, which is produced previously, the thickness of the n-type (or p-type) thermoelectric conversion parts should be the same as the thickness of the p-type thermoelectric conversion parts 7 which have been produced previously. Here, powder of a semiconductor thermoelectric conversion material of Bi₂Te₃ (70% by volume) and semiconductor glass powder (30% by volume) containing vanadium oxides, tellurium dioxide (TeO₂) and silver(I) oxide (Ag₂O) were used for the n-type semiconductor thermoelectric conversion material.

Thus, each of the substrate in which the p-type thermoelectric conversion composite material paste has been coated and the substrate in which the n-type thermoelectric conversion composite material paste has been coated, which have been independently produced, is dried at a temperature of about 150° C. for 10 minutes to vaporize the solvent and pre-calcined at a temperature of about 380° C. for 30 minutes to remove the binder.

A cross-sectional diagram after then adhering the substrates in such a way that the thermoelectric conversion parts are connected in series with the polarities (p-type and n-type) aligned alternately is shown in FIG. 10F. After FIG. 10F, by applying a weight, calcining at a temperature about 20 to 30° C. higher than the softening points of the semiconductor glasses and thus melting the semiconductor glasses, sintering is conducted. Here, the substrates were adhered and calcined after drying and pre-calcining, but it is also possible to dry and pre-calcine after the substrates are adhered. In this case, it is desirable to insert spacers so that the coated pastes would not be crushed.

Lastly, a cross-sectional diagram after sealing with a sealant 16 made from a glass paste for sealing or glass frit in vacuum is shown in FIG. 10G. The sealant 16 is disposed to reduce the loss of the thermoelectric conversion. By vacuumizing the inside of the thermoelectric conversion device, the heat supplied to the top and the bottom of the support substrates from outside transmits mainly through the thermoelectric conversion parts and thus the loss of the heat is reduced.

Although a production process of a π-type thermoelectric conversion device is shown in FIG. 10, it is also acceptable to produce a thermoelectric conversion device of so-called uni-leg type, which is made from the p-type or n-type thermoelectric conversion material only.

### EXAMPLE 2

As shown in Example 1, the electrode materials which do not aggregate due to the thermoelectric conversion composite material containing the semiconductor glass as the base material are Ti, Ti nitride, W, W nitride, W silicide, Ta, Cr, Si and Al. However, Ti, Ti nitride, W, W nitride, W silicide, Ta, Cr and Si have higher resistivities than Cu, Au and the like. In addition, because Ti, Ti nitride, W, W nitride, W silicide, Ta and Cr are rare metals, it is not preferable to increase the electrode thickness to reduce the resistance. On the other hand, although Al has a low resistivity and can be obtained easily, there is a problem that the surface of Al is oxidized by calcination at a high temperature.

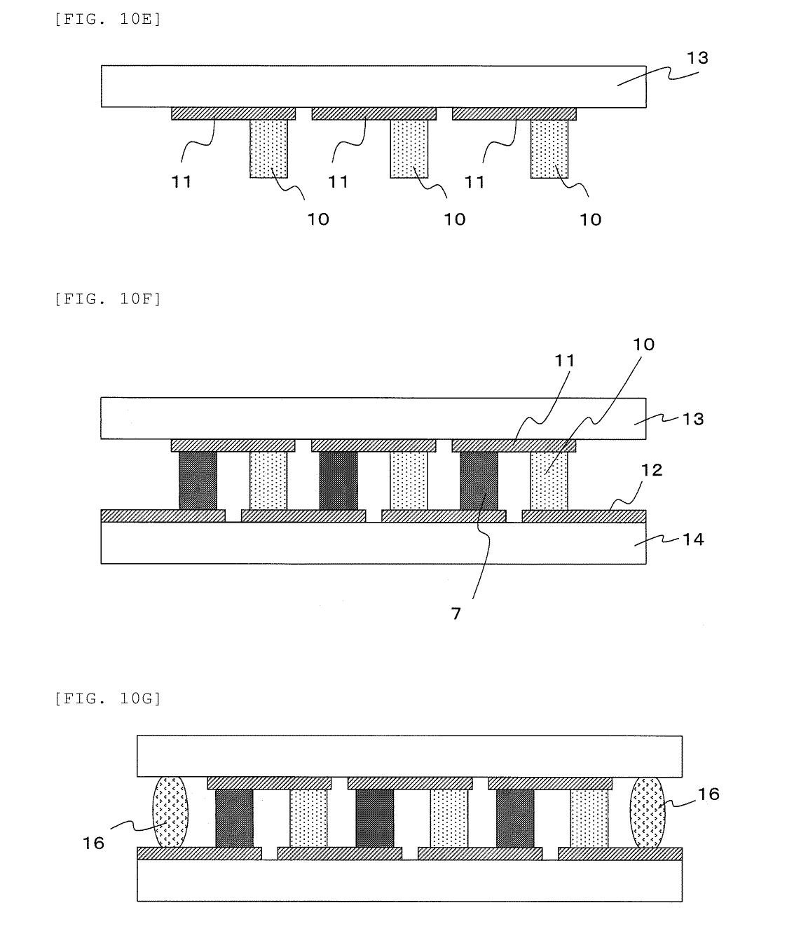

As a constitution to solve the problem, the n-type (or p-type) thermoelectric conversion composite material and a part of the electrodes and the support substrates of a thermoelectric conversion device according to Example 2 are shown in FIG. 11. Here, an upper electrode 31 is a multi-layer electrode containing an upper surface electrode layer 22 and an upper low-resistant electrode layer 23, wherein the distance between upper low-resistant electrode layer 23 and the thermoelectric conversion part 10 is longer than the distance between upper surface electrode layer 22 and the thermoelectric conversion part 10. Similarly, a lower electrode 32 has a laminate structure containing a lower surface electrode layer 24 and a lower low-resistant electrode layer 25, wherein the distance between the lower low-resistant electrode layer 25 and the thermoelectric conversion part 10 is longer than the distance between the lower surface electrode layer 24 and the thermoelectric conversion part 10.

Here, the upper surface electrode layer 22 and the lower surface electrode layer 24 are any of Ti, Ti nitride, W, W nitride, W silicide, Ta, Cr and Si, which are electrode materials which do not aggregate due to the thermoelectric conversion part 10 and are not oxidized by calcination at a high temperature.

On the other hand, the upper low-resistant electrode layer 23 and the lower low-resistant electrode layer 25 are any of Al, Cu, Au and Ag which are low resistant.

By making the upper electrode 31 and the lower electrode 32 as such multi-layer electrodes, the upper surface electrode layer 22 and the lower surface electrode layer 24 do not aggregate due to the thermoelectric conversion composite material and are not oxidized by calcination at a high temperature. Also, due to the upper low-resistant electrode layer 23 and the lower low-resistant electrode layer 25, the resistance values of the whole electrodes can be reduced. Accordingly, the electrodes which do not aggregate due to the thermoelectric conversion composite material and have low resistance can be obtained, and an effect of preventing the voltage drop of the thermoelectric power generated at the electrode parts can be obtained. The electric current flowing from the thermoelectric conversion part 10 flows through the surface electrode layers 22 and 24 of the electrodes neighboring the thermoelectric conversion composite material, flows through the low-resistant electrode layers 23 and 25, and flows to the thermoelectric conversion part formed adjacent to the layers.

As described above, the thermoelectric conversion device according to this Example contains the support substrate, the electrode formed on the support substrate, and the thermoelectric conversion part formed on the electrode and containing semiconductor glass, and is characterized in that the semiconductor glass is non- lead glass containing vanadium, the electrode (31 or 32) has a laminate structure containing a first electrode layer (22 or 24) and a second electrode layer (23 or 25), wherein the distance between the second electrode layer and the thermoelectric conversion part is longer than the distance between the first electrode layer and the thermoelectric conversion part, the first electrode layer contains any of Ti, Ti nitride, W, W nitride, W silicide, Ta, Cr and Si, and the second electrode layer contains any of Al, Cu, Au and Ag.

By this constitution, in the thermoelectric conversion device according to this Example, the first electrode layer does not aggregate due to the thermoelectric conversion composite material and is not oxidized by calcination at a high temperature. In addition, due to the second electrode layer, the resistance value of the whole electrode can be decreased. Accordingly, by this constitution, the reliability comparable to that of Example 1 can be ensured and a thermoelectric conversion device with excellent characteristics can be achieved.

### EXAMPLE 3

The thermoelectric conversion device according to Example 3 is shown in FIG. 12. The materials which aggregate as described above are materials which strongly react with the thermoelectric conversion composite material. Using this property, the materials which aggregate can be used for a binding layer to enhance the binding of the thermoelectric conversion composite material and the electrode.

In the constitution shown in FIG. 12, the thermoelectric conversion part 10 containing the thermoelectric conversion part 10 semiconductor thermoelectric conversion material 9 and the semiconductor glass 8, the upper electrode 31 containing the upper surface electrode layer 22 and the upper low-resistant electrode layer 23, and the lower electrode 32 containing the lower surface electrode layer 24 and the lower low-resistant electrode layer 25 are similar to those of Example 1. On the other hand, the constitution is different from that of Example 1 in that a binding layer 26 is disposed between the thermoelectric conversion part 10 and the upper surface electrode layer 22 and a binding layer 27 is disposed between the thermoelectric conversion part 10 and the lower surface electrode layer 24. The binding layers 26 and 27 are both made from materials which aggregate.

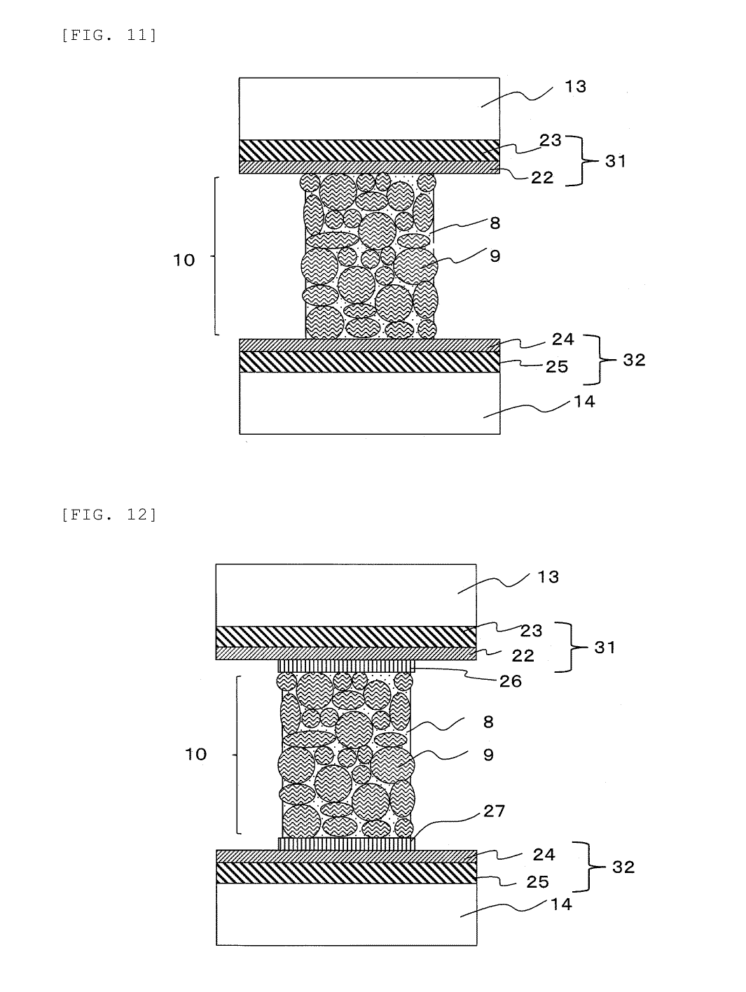

The effect of such insertion of the binding layers 26 and 27 is explained using FIG. 13. The effect is explained below with an example of the lower binding layer 27; however, the same discussion can be applied to the binding layer 26. In addition, the effect is explained with an example of the thermoelectric conversion part 10; however, the same discussion can be applied to the thermoelectric conversion part 7. As shown in FIG. 13A, in case of an electrode of a single layer made from a material which aggregates, when the electrode layer 27 aggregates, breaks occur at the points where there is no aggregated particles and an electric current 28 does not flow. On the other hand, in case of the thermoelectric conversion device according to this Example, even when the binding layer aggregates, the electric current flows to the underlying electrode layer which is made from a material which does not aggregate and is in contact with the binding layer.

A case of multi-layer electrode structures in which the upper surface electrode layer 22 and the lower surface electrode layer 24 are made from materials which do not aggregate is shown in FIG. 13B. As it can be seen from FIG. 13B, even when the binding layer 27 aggregates, the electric current 28 flows through the lower surface electrode layer 24 which does not aggregate and flows to the underlying lower low-resistant electrode layer 25. Because the thermoelectric conversion part 10 and the lower outermost surface layer 24 are always connected through the binding layer 27, the electronic current is not cut. Although the cross-sectional area of the binding layer 27 may reduce and resistance may increase due to the aggregation, the contact resistance reduces due to the strong chemical binding between the materials and thus the increase in the resistivity as a whole is not high.

In addition, because of the binding layers 26 and 27, the mechanical binding of the thermoelectric conversion composite materials and the electrode layers also becomes stronger and the mechanical strength of the whole thermoelectric conversion device also increases.

Thus, the thermoelectric conversion device according to this Example is characterized in that the electrode (31 or 32) is connected to the thermoelectric conversion part (7 or 10) through the binding layer (26 or 27) and the binding layer contains any of Au, Pt, Mo, MoN, Ni, Co, Fe and Ag.

Due to this characteristic, in the thermoelectric conversion device according to this Example, the increase in the resistivity as a whole can be prevented and the mechanical strength of the thermoelectric conversion device as a whole can be increased.

### EXAMPLE 4

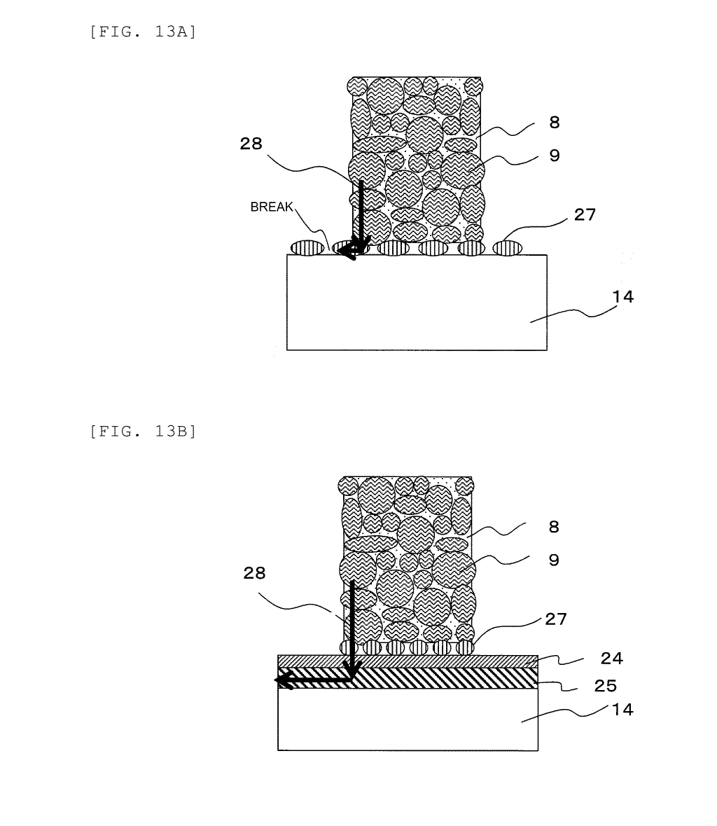

In the production process explained in Example 1, the substrate in which the p-type thermoelectric material has been coated and the substrate in which the n-type thermoelectric material has been coated have been dried and pre-calcined, and then adhered to each other and calcined. However, it is also possible to calcine the thermoelectric conversion part on each substrate before the substrates are adhered and the sintered thermoelectric conversion part can be connected to the other electrode using an electrically conductive paste. The production process is explained in FIG. 14. In FIG. 14A, electrically conductive paste 29 has been coated on the surface of the n-type (or p-type) thermoelectric conversion part 10 sintered on the electrode 11, and in FIG. 14B, the electrically conductive paste 29 has been similarly coated on the surface of the p-type (or n-type) thermoelectric conversion part 7. The electrically conductive paste can be coated by stencil printing, screen printing or printing using a dispenser. These substrates are adhered in such a way that the p-type and n-type thermoelectric conversion parts are connected to the electrodes alternately, as shown in FIG. 14C. Although the electrically conductive paste has been coated on the surfaces of the thermoelectric conversion parts in the figure, it is also acceptable to coat the electrically conductive paste on the electrode sides to be adhered.

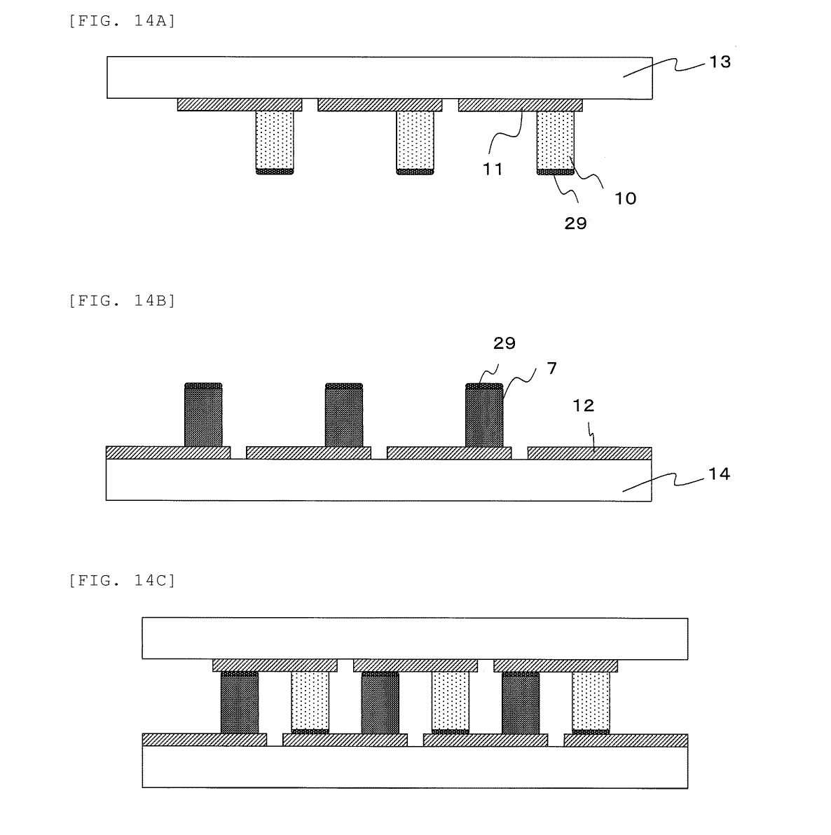

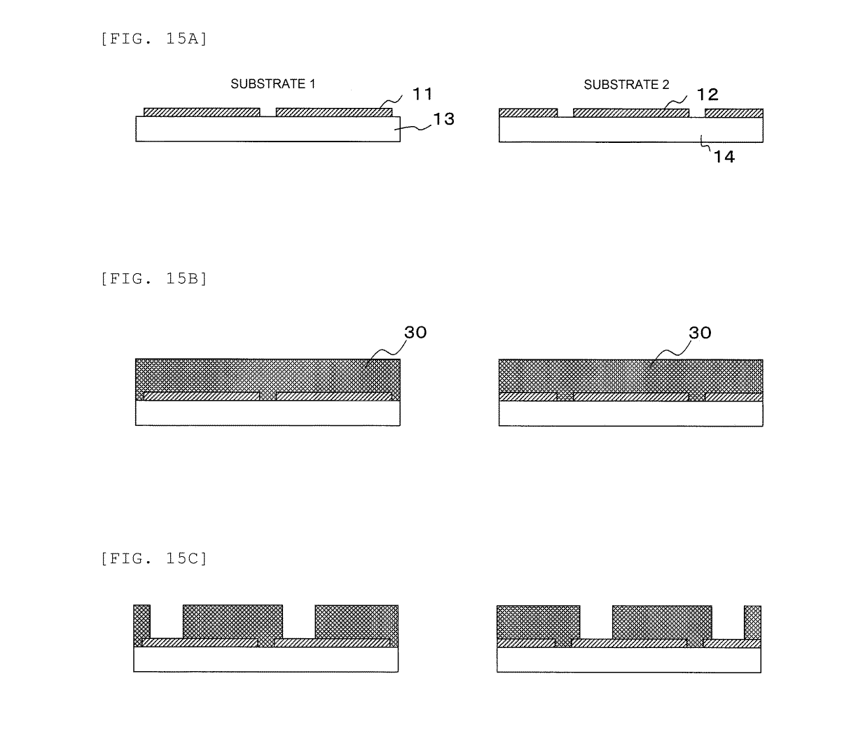

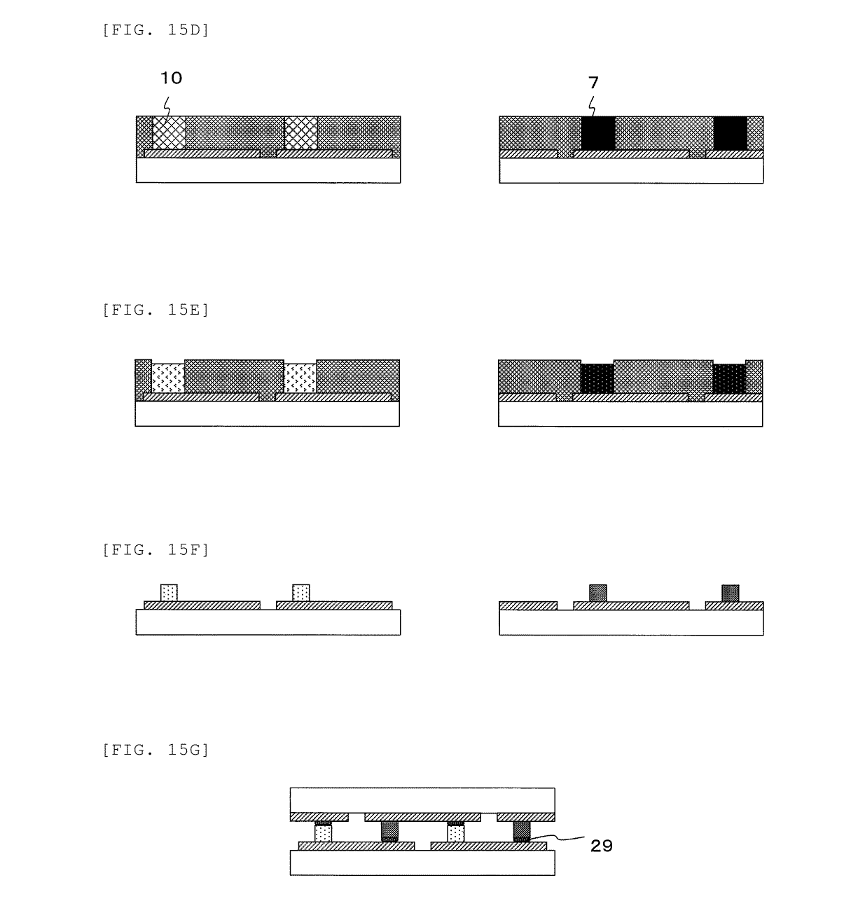

When the production process according to this Example is used, it is also possible to produce each of the parts shown in FIGS. 14A and 14B by drawing patterns of the thermoelectric conversion parts using a dry film resist. Such a production process is explained in FIG. 15.

First, substrates with an electrode pattern are prepared as shown in FIG. 15A. This step may be similar to the steps of FIG. 10A to FIG. 10C of Example 1, and two kinds of substrate (a substrate 1 and a substrate 2) are produced for the p-type and n-type thermoelectric conversion parts. Then, as shown in FIG. 15B, a dry film resist 30 which disappears by heat is adhered to the surfaces of substrate 1 and substrate 2. Considering the amounts of the vaporizing solvents and the like in the thermoelectric conversion material pastes, the thickness of the film should be a little larger than the desired thickness of the thermoelectric conversion parts. It is possible to prepare a thick film by piling and adhering thin films. Then, as shown in FIG. 15C, light-exposure using masks and development are conducted and patterns are formed on the films. Next, as shown in FIG. 15D, a paste or a slurry with a lower concentration of the n-type (or p-type) thermoelectric conversion composite material is poured into the pattern on the substrate 1 and a paste or a slurry of the p-type (or n-type) thermoelectric conversion composite material is poured into the pattern on the substrate 2. Then, as shown in FIG. 15E, the solvents and the binders are vaporized by drying and pre-calcination. At this point, the pastes or the slurries of the thermoelectric conversion composite materials include the semiconductor thermoelectric conversion materials and the semiconductor glasses only and their volumes are reduced. Next, each substrate is calcined as in FIG. 15F. The semiconductor glasses in the thermoelectric conversion composite materials melt in this step and the thermoelectric conversion composite materials are sintered. In addition, the dry film resist 30 disappears at the same time. Finally, as shown in FIG. 15F, the substrate 1 and the substrate 2 are adhered to each other with the electrically conductive paste 29.

When the thermoelectric conversion parts 7 and 10 are thus formed using a dry film resist, the dry film resist used as the molds for the thermoelectric conversion parts is thermally decomposed and disappears. Therefore, the deformation of edges (corners) of the pastes, which occurs when the pastes are extruded from a mask as in stencil printing and screen printing, does not occur and a thermoelectric conversion parts excellent in the thickness evenness can be formed.

### REFERENCE SIGNS LIST

1 Semiconductor glass powder

2 Semiconductor thermoelectric conversion material

3 Space

4 Melted semiconductor glass

5 Semiconductor glass

6 p-Type semiconductor thermoelectric conversion material

7 p-Type thermoelectric conversion composite material

8 Semiconductor glass

9 n-Type semiconductor thermoelectric conversion material

10 n-Type thermoelectric conversion composite material

11 Upper electrode

12 Lower electrode

13 Upper support substrate

14 Lower support substrate

15 Electrode film

16 Sealant

17 Au electrode

18 Thermoelectric conversion composite material

19 Degenerated area of electrode

20 A part of degenerated area of electrode

21 Au particle

22 Outermost surface layer of upper electrode

23 Low-resistant electrode layer of upper electrode

24 Outermost surface layer of lower electrode

25 Low-resistant electrode layer of lower electrode

26 Binding layer of upper electrode

27 Binding layer of lower electrode

28 Flow of electric current

29 Electrically conductive paste

30 Dry film resist

31 Upper electrode

32 Lower electrode.

1. A thermoelectric conversion device comprising
a support substrate,
an electrode formed on the support substrate, and
a thermoelectric conversion part formed on the electrode and containing semiconductor glass,
wherein the semiconductor glass is non-lead glass containing vanadium, and
the electrode contains any of Al, Ti, Ti nitride, W, W nitride, W silicide, Ta, Cr and Si.

2. The thermoelectric conversion device of claim 1,
wherein the thermoelectric conversion part further comprises a semiconductor thermoelectric conversion material, and
the semiconductor thermoelectric conversion material contains at least one kind of a Bi—(Te,Se,Sn,Sb) material, a Pb—Te material, a Zn—Sb material, an Mg—Si material, an Si—Ge material, a GeTe—AgSbTe material, a (Co,Ir,Ru)—Sb material, a (Ca,Sr,Bi)Co₂O₅ material, an Fe—Si material and an Fe—V—Al material.

3. The thermoelectric conversion device of claim 1,
wherein the electrode has a laminate structure comprising a first electrode layer and a second electrode layer, wherein the distance between the second electrode layer and the thermoelectric conversion part is longer than the distance between the first electrode layer and the thermoelectric conversion part,
the first electrode layer contains any of Ti, Ti nitride, W, W nitride, W silicide, Ta, Cr and Si, and
the second electrode layer contains any of Al, Cu, Au and Ag.

4. The thermoelectric conversion device of claim 1,
wherein the electrode is in direct contact with the thermoelectric conversion part.

5. The thermoelectric conversion device of claim 1,
wherein the electrode is connected to the thermoelectric conversion part through a binding layer, and
the binding layer contains any of Au, Pt, Mo, MoN, Ni, Co, Fe and Ag.
